(19) United States
(12) Patent Application Publication
(10) Pub. No.: US 2024/0147654 A1
(43) Pub. Date: May 2, 2024

(54) LAPTOP ARRANGEMENT FOR HEAT CONTROL

(71) Applicant: Intel Corporation, Santa Clara, CA (US)

(72) Inventors: Jiunn Shyong CHEE, Bayan Lepas (MY); Howe Yin LOO, Bayan Lepas (MY); Tin Poay CHUAH, Bayan Lepas (MY); Chin Kung GOH, Tanjung Tokong (MY); Yew San LIM, Gelugor (MY)

(21) Appl. No.: 18/050,502

(22) Filed: Oct. 28, 2022

(51) Int. Cl. H05K 7/20; G06F 1/20

(52) U.S. Cl. CPC H05K 7/20136; G06F 1/203

(57) ABSTRACT

The present disclosure is directed to a laptop arrangement including: a chassis defining a space that is divided into a first compartment and a second compartment, the first compartment including an air inlet and the second compartment including an air outlet; and a partitioning element positioned between the first and second compartments, whereby the partitioning element at least partially seals the first compartment from the second compartment and enables the second compartment to have a greater pressurization than the first compartment.

### BACKGROUND

As laptops are getting thinner, a skin temperature of keyboards becomes a limiting factor for power handling capability. For example, an acceptable skin temperature of keyboards may be 42° C. There is therefore a need to reduce the skin temperature of keyboards.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity. In the following description, various aspects of the present disclosure are described with reference to the following drawings, in which:

FIG. 1A is a top view of a conventional laptop arrangement;

FIG. 1B is a cross-sectional view of a conventional laptop arrangement;

FIG. 2 is a top view of a conventional laptop arrangement;

FIG. 3A is a top view of a conventional laptop arrangement;

FIG. 3B is a cross-sectional view of a conventional laptop arrangement;

FIG. 4A is a top view of a laptop arrangement according to the disclosure;

FIG. 4B is a cross-sectional view of a laptop arrangement according to the disclosure;

FIG. 5A is a top view of a laptop arrangement according to the disclosure;

FIG. 5B is a cross-sectional view of a laptop arrangement according to the disclosure;

FIG. 5C is a cross-sectional view of a laptop arrangement according to the disclosure;

FIG. 6 is a top view of a laptop arrangement according to the disclosure;

FIG. 7 is a top view of a laptop arrangement according to the disclosure;

FIG. 8 shows a simplified flow diagram for an exemplary method according to an aspect of the present disclosure.

FIG. 9 is a diagram illustrating the effectiveness of aspects according to the disclosure;

FIG. 10 is a diagram illustrating the effectiveness of aspects according to the disclosure;

FIG. 11A and FIG. 11B are thermal images illustrating the effectiveness of aspects according to the disclosure;

FIG. 12 is a diagram illustrating the effectiveness of aspects according to the disclosure;

FIGS. 13A-13D are thermal images illustrating the effectiveness of aspects according to the disclosure; and

FIG. 14 is a thermal image illustrating the effectiveness of aspects according to the disclosure, by illustrating the air velocity for a fan having a thickness of 7.5 mm.

### DETAILED DESCRIPTION

The thermal design in a laptop arrangement is typically a bottleneck for meeting higher power and higher performance, especially where laptops are getting thinner. Previous thermal designs may not meet today's expectations with regard to a power dissipation requirement while maintaining an acceptable keyboard skin temperature.

For example, in a conventional 45 W RPL-Px+10 W DG2 laptop with 10.3 mm chassis height, the keyboard skin temperature may reach 46° C. However, for some customers, an upper limit for an acceptable keyboard skin temperature is 42° C. Hence, in order to meet industry standards in terms of Cool Quiet Performance, a reduction of the keyboard skin temperature is desirable as thermal comfort is typically prioritized over performance.

In previous laptop arrangements, two of the thickest components (a fan and a keyboard) are typically in a same stack-up path, e.g., in vertical alignment with each other, or at least vertically overlapping. A consequence is, that a fan thickness, when retaining the same laptop thickness, is limited. This may cause a constraint on the fan thickness, leading to a performance limitation for the fan.

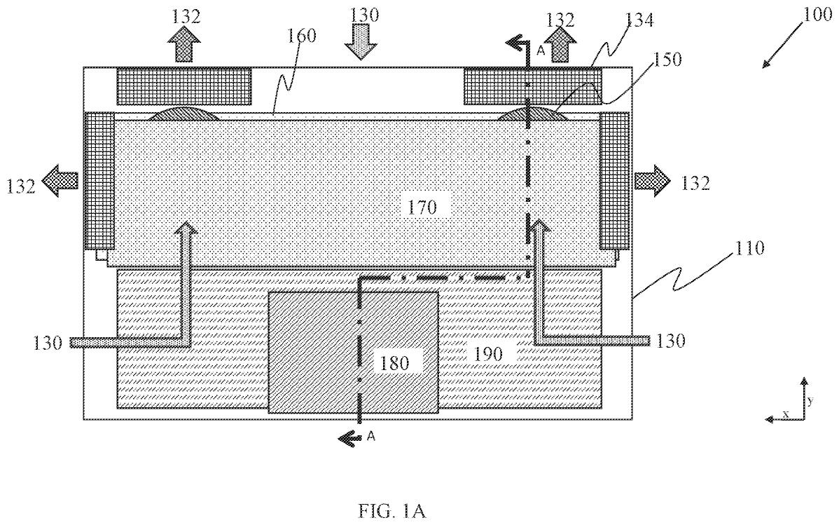

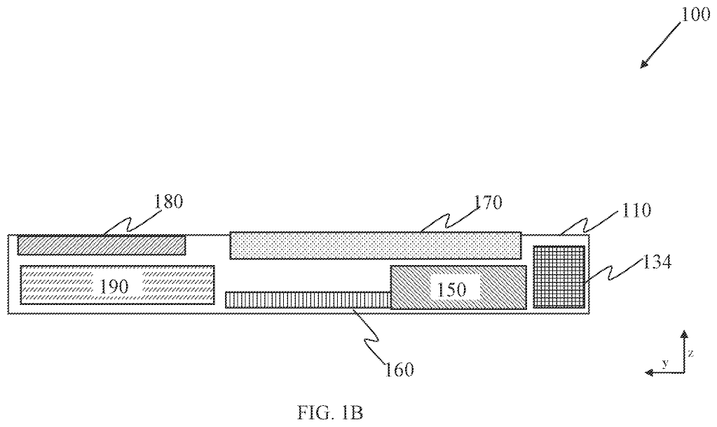

For example, one conventional laptop arrangement is shown in FIG. 1A and FIG. 1B. The laptop arrangement 100 shown in FIG. 1A may have a chassis 110, with several laptop components positioned therein. With regard to the air circulation, an air inflow 130, positioned adjacent to the fans 150 between two heat exchangers 134 or positioned adjacent to a battery pack 190, circulates through the chassis 110 and leaves the chassis 110 at air outlets 132, and through heat exchangers 134. FIG. 1A also shows a keyboard 170, vertically overlapping with fans 150 and the battery pack 190 vertically overlapping with a touch pad 180. “Vertically overlapping”, whenever used herein, is meant to indicate that components are overlapping in the x-y plane in FIG. 1A, such that they are partially obscured. In the cross-section along the line A-A, illustrated in FIG. 1B, it is shown that the fan 150 is underneath the keyboard 170, preventing the fan 150 to increase its thickness while retaining the same overall chassis thickness. “Underneath”, whenever used herein, is meant to indicate that components are overlapping in the z direction, as shown in FIG. 1B. The same terminology applies to remaining description.

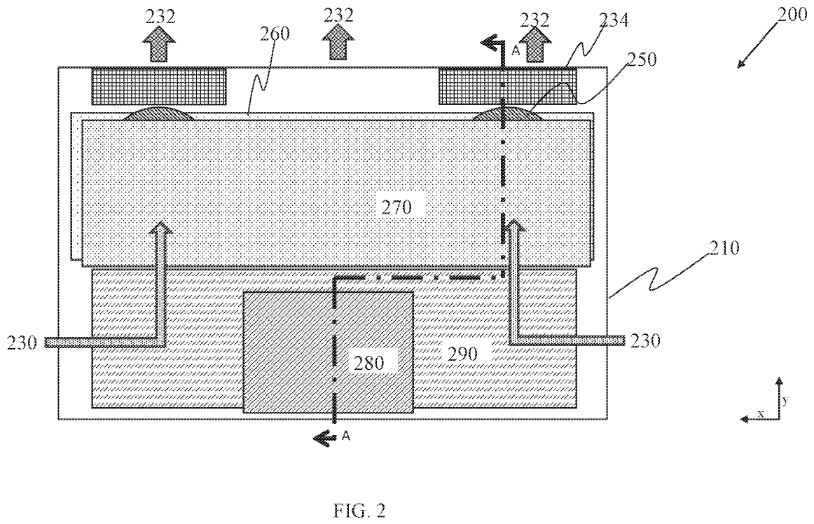

Another conventional laptop arrangement is shown in FIG. 2. The laptop arrangement 200 shown in FIG. 2 may also have a chassis 210, with several laptop components positioned therein. With regard to the air circulation, an air inflow 230, positioned adjacent to a battery pack 290, circulates through the chassis 210 and leaves the chassis 210 at the air outlets 232, and through heat exchangers 234. The cross-sectional view through the line A-A would not differ from the cross-sectional view illustrated in FIG. 1B, meaning that also in this example, the fan 250 is underneath the keyboard 270, preventing the fan 250 to increase its thickness while retaining the same overall chassis thickness.

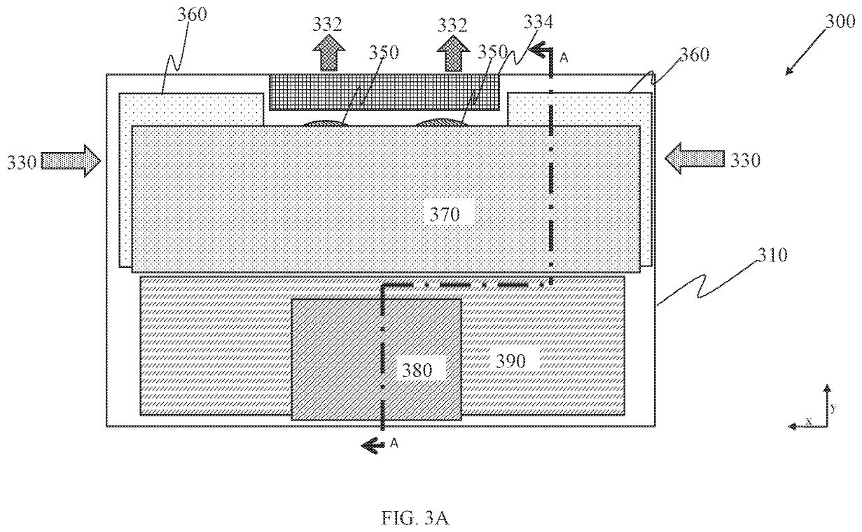

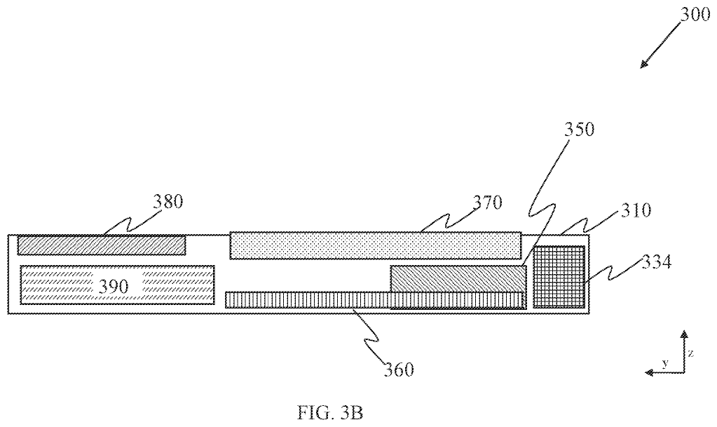

Another conventional laptop arrangement is shown in FIG. 3A and FIG. 3B. The laptop arrangement 300 shown in FIG. 3 may also have a chassis 310, with several laptop components positioned therein. With regard to the air circulation, an air inflow 330, positioned adjacent to computing components 360, circulates through the chassis 310 and leaves the chassis 310 at the air outlets 332, and through the heat exchanger 334. In the cross-section along the line A-A, illustrated in FIG. 3B, it is shown that the fan 350 is also underneath the keyboard 370, preventing the fan 350 to increase its thickness while retaining the same overall chassis thickness.

In all of the above conventional laptop arrangements, the fans 150, 250 and 350 are all positioned adjacent to (e.g., proximal to) the air outflow. Consequently, the airflow would have passed all heat-generating components (e.g., computing components 160, 360) before reaching the fans 150, 250 and 350. The consequence of these conventional arrangements is that a keyboard skin temperature in the conventional arrangements 100, 200 and 300 may be too high and therefore cause discomfort for the customer. A laptop arrangement capable of reducing the keyboard skin temperature while retaining the same laptop thickness would therefore be advantageous to obtain a higher customer satisfaction.

To address the above insufficiency, the present disclosure provides a laptop arrangement that may enable a reduced keyboard skin temperature while retaining the same laptop thickness.

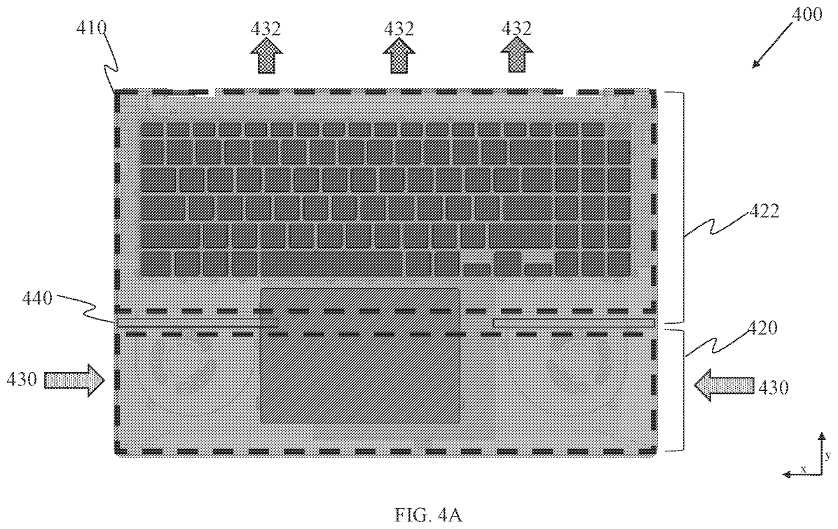

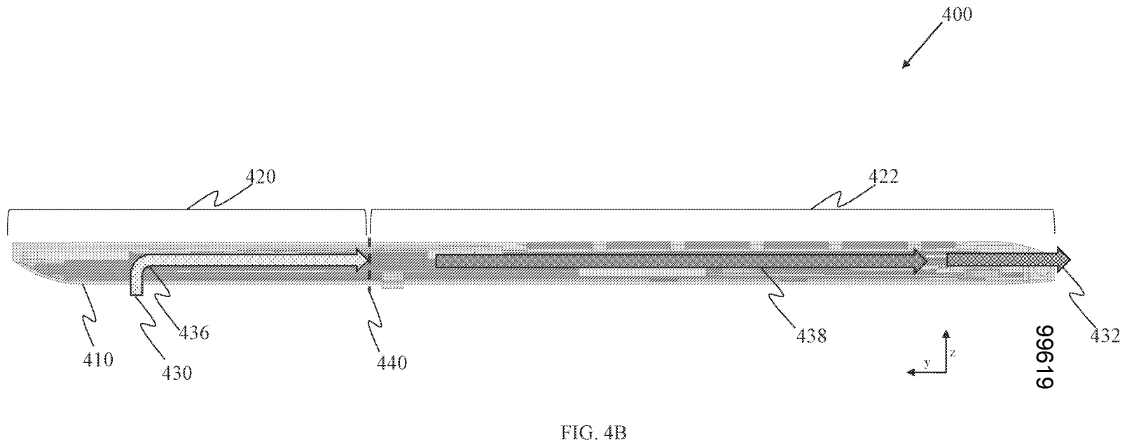

Accordingly, in a first aspect, as shown in FIG. 4A, there is provided a laptop arrangement 400 including a chassis 410 defining a space that is divided into a first compartment 420 and a second compartment 422. The first compartment 420 may include an air inlet 430 and the second compartment may include an air outlet 432. The laptop arrangement 400 may further include a partitioning element 440 positioned between the first and second compartments 420, 422, whereby the partitioning element 440 at least partially seals the first compartment 420 from the second compartment 422 and enables the second compartment 422 to have a greater pressurization than the first compartment 420. FIG. 4A shows the laptop arrangement 400 in a top view while FIG. 4B refers to the laptop arrangement 400 of FIG. 4A in a cross-sectional view.

The laptop arrangement 400 may also be termed a “Dual Compartment” arrangement, having one compartment (e.g., the first compartment 420), that is at an ambient pressure, while another compartment (e.g., the second compartment 422) may be a compartment where the airflow is heated up from heat-generating components, due to the partitioning element 440, and which may have a pressure that is higher than ambient pressure. The difference in pressure may be due to the partitioning element 440, which partially seals the airflow such that an airflow back to the first compartment 420 may not take place.

FIG. 4B further specifies the airflow, showing the air inlet 430 (e.g., an inlet vent) and the air outlet 432 (e.g., an outlet vent), and the airflow may be generally in a direction from the air inlet 430 to the air outlet 432. In more detail, after air has entered the chassis 410 through air inlet 430 in the first compartment 420, the airflow may be rotated at 436 by about 90°, e.g., by a fan (not shown), such that the airflow may be in alignment with the length of the chassis 410. The airflow may then enter the second compartment 422 through the partitioning element 440, and may gradually heat up by taking up heat from the heat-generating components (not shown) in the laptop arrangement 400 until reaching the air outlet 432. Optionally, the airflow may be passed through a heat exchanger (not shown) before being dissipated through the air outlet 434.

According to some aspects, the partitioning element 440 may be an air seal gasket. More specifically, the partitioning element 440 may include a foam seal.

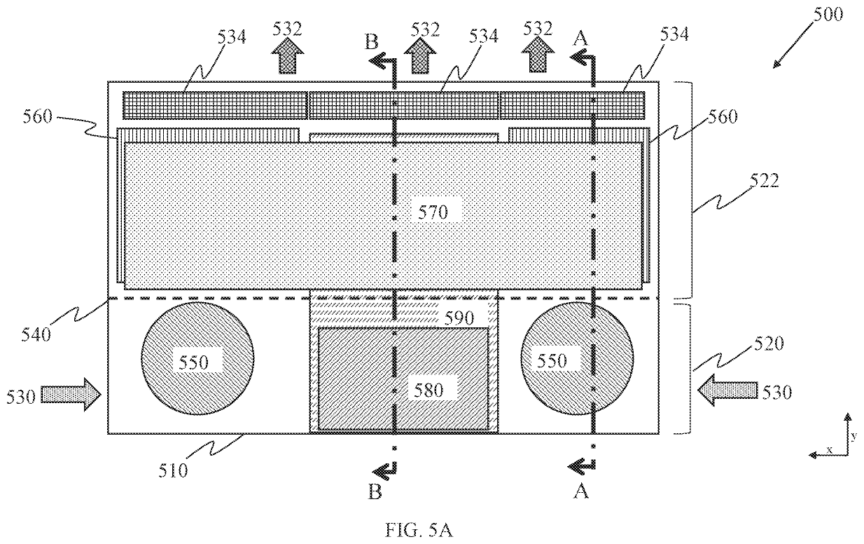

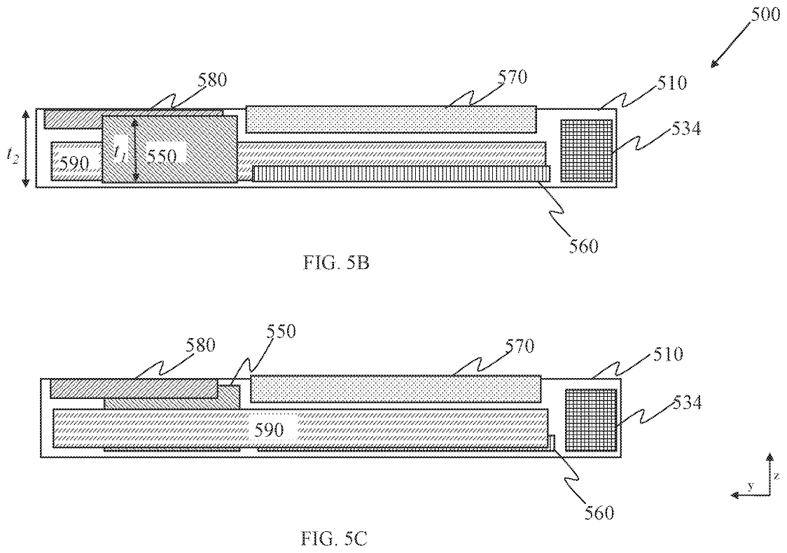

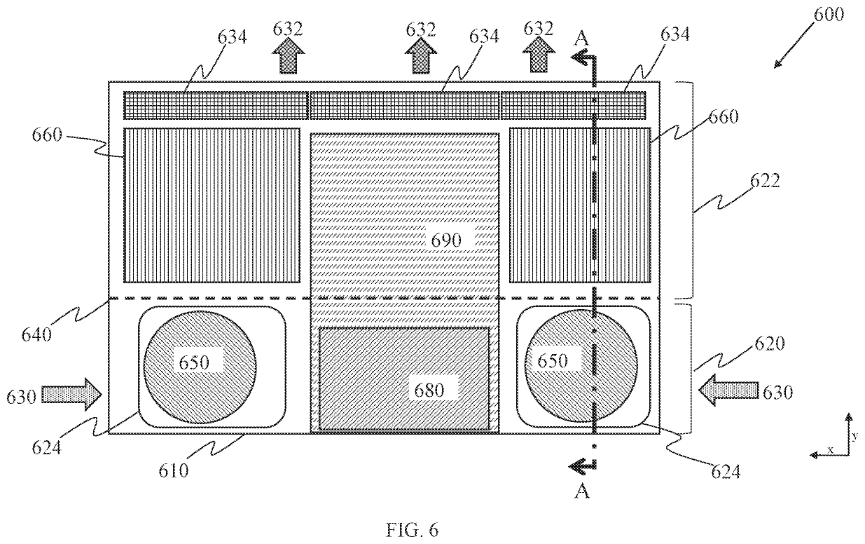

In some aspects, as shown in FIG. 5A, the laptop arrangement 500 may additionally include a fan 550. The fan may be positioned in the first compartment 520 of the chassis 510 and may cause the airflow to be rotated, e.g., by about 90°, such that the airflow may be in alignment with the length of the chassis 510. In other words, when the airflow enters the first compartment 520 through air inlet 530, it may reach the fan 550 and the direction of the airflow may be changed. Moreover, the fan 550 may cause the airflow to enter the second compartment 522 through the partitioning element 540. Additionally, an air velocity downstream of the fan 550, e.g., when entering the second compartment 522, may be higher than an air velocity upstream of the fan 550, e.g., when entering the second compartment 522 and before reaching the fan 550. Moreover, the airflow may also be stronger and more concentrated downstream of the fan 550, and before reaching the air outlet 532. Accordingly, when the airflow reaches the second compartment 522, it may be more capable of removing heat from the heat-generating components positioned therein, e.g., by convectively dissipating the heat from the heat-generating components.

In some aspects, the laptop arrangement 500 may additionally include a computing component 560, which may be positioned in the second compartment 522. The computing component 560 may be selected from the group consisting of a motherboard, a central processing unit (CPU), a graphic processing unit (GPU), or a combination thereof. The computing component 560 may further include a motherboard that houses a GPU (e.g., a G-card), or a motherboard that houses a CPU (e.g., a C-card). The terms G-card and C-card may describe two separate motherboards in a split-board or multiple-board design. The computing component 560 may further include a motherboard that houses both CPU and GPU in a single motherboard, which may be called a main board, or a main card. Generally, the computing component 560 may be a heat-generating component, e.g., a component that, while being used, generates heat that may potentially heat up a keyboard 570, located on top of the computing component 560.

In some aspects, the laptop arrangement 500 may additionally include a heat exchanger 534, which may be positioned in the second compartment 522 adjacent to the air outlet 532, and along a side of the chassis 510 that is facing away from a user.

In some aspects, the laptop arrangement 500 may additionally include a touch pad 580, positioned in the first compartment 520, and vertically overlapping with (e.g., on top of) a battery pack 590.

FIG. 5B refers to the laptop arrangement 500 of FIG. 5A in a cross-sectional view along the line A-A. As shown therein, a thickness of the fan 550 is not impeded by a competing thickness of the keyboard 570, but only limited by the total thickness of the chassis 510. Hence, in this aspect, it is possible to increase the thickness t₁ of the fan, thereby increasing its performance, while retaining a thickness t₂ of the chassis 510. In conventional laptop arrangements 100, 200, 300, increasing a thickness of the fan 150, 250, 350 would have caused an increased thickness of the chassis 110, 210, 310, which may not be necessary with laptop arrangement 500. FIG. 5C is an additional cross-sectional view along the line B-B, which is an additional illustration of the increased thickness of the fan 550 within the chassis 510.

Accordingly, in some aspects, a thickness t₂ of the chassis 510 of the laptop arrangement 500 may be about 9 to 14 mm, or about 10 to 13 mm, or about 9, 10, 11, 12, 13, 14 mm. A corresponding t₁ of the fan 550 may be about 6 to 8 mm, or about 7 to 7.5 mm or about, 6, 7, or 7.5 mm. Hence, the thickness t₁ of the fan 550 may be more than, or about, 50%, or more than, or about, 60%, or more than, or about, 70% or more than, or about, 80% of the thickness t₂ of the chassis 510. Advantageously, this provides a beneficial ratio between t₁ and t₂ that retains the thickness of the chassis at a customer-friendly standard while decreasing the keyboard skin temperature due to the higher performance of the comparatively thick fan 550.

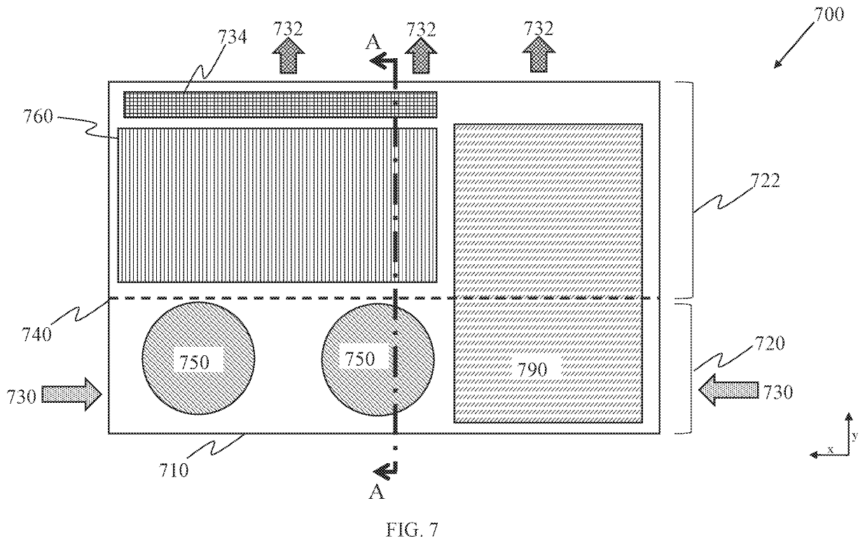

In one aspect, as shown in FIG. 6, the laptop arrangement 600 may include all the components of the laptop arrangement 500 (keyboard not shown for visibility of underlying components), and may further include two fans 650. Further specified in FIG. 6 is a palm rest region 624, e.g., two palm rest regions 624. The palm rest region 624 may be typically used by the user to place their palms on while typing on the keyboard. This area is typically not sufficiently utilized in the conventional laptop arrangements. Accordingly, in aspects where two fans 650 are present, these two fans 650 may be placed underneath the palm rest regions 624, which advantageously provides for a better use of the previously insufficiently used space underneath the palm rest regions 624. A cross-sectional view of the laptop arrangement 600 would not differ from the cross-sectional view outlined in FIG. 5B for the laptop arrangement 500 and is therefore omitted for brevity.

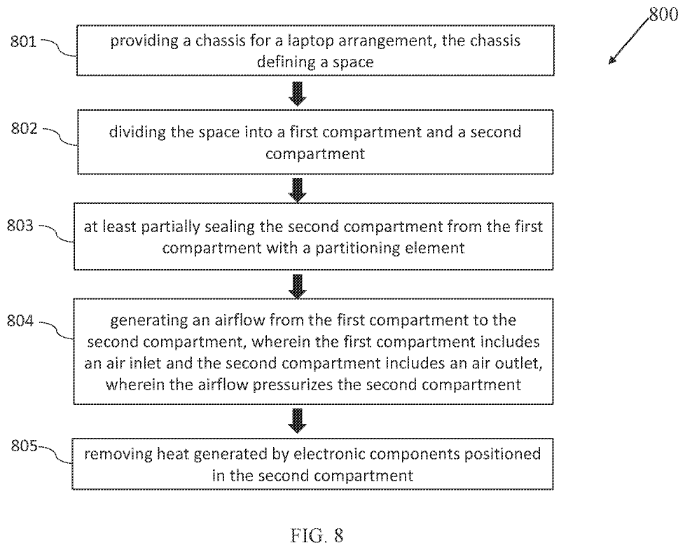

Alternatively, in aspects, where two fans are present, and as shown in FIG. 7, two fans 750 could be arranged adjacent to each other, whereby one of the two fans 750 would be positioned underneath a touch pad (not shown). The space underneath the two palm rest regions specified in FIG. 6 would then be occupied by a battery pack or the second fan 750.

In another aspect, there is provided a laptop. The laptop may have a laptop arrangement such as that illustrated in FIGS. 4A, 4B, 5A, 5B, 5C, and 6. The same terms are used for the description of this aspect as for the description of the above FIGS. The laptop may include a chassis, whereby the chassis defines a space that is divided into a first compartment and a second compartment; the first compartment including an air inlet and the second compartment including an air outlet; whereby a partitioning element may be positioned between the first and second compartments, whereby the partitioning element may at least partially seal the first compartment from the second compartment and may enable the second compartment to have a greater pressurization than the first compartment. The laptop may further include a plurality of laptop components, whereby the laptop components may include a computing component, two fans, a keyboard, a battery pack and a touch pad, whereby the keyboard and the computing component may be positioned in the second compartment, and the two fans and the touch pad may be positioned in the first compartment. The computing component and the two fans may be positioned adjacent to each other within the chassis, whereby the keyboard may be positioned horizontally offset from the two fans, and whereby the battery pack may be positioned vertically offset from the keyboard. The touch pad may be interposed between the two fans. In further detail, the computing component and the two fans may be positioned adjacent to each other in a plane x-y within the chassis and an airflow in the chassis may approach the two fans from an upstream direction and may depart from the fan in a downstream direction. The computing component may be positioned downstream of the two fans. The laptop may further include a keyboard that is positioned horizontally offset from the fan (e.g., not horizontally overlapping, e.g., not overlapping in the x-y plane). The laptop may further include a battery pack that is positioned vertically offset from the keyboard.

In another aspect, there is provided a chassis for a laptop computer including: a first compartment and a second compartment, the first compartment including an air inlet and the second compartment including an air outlet; and a partitioning element positioned between the first and second compartments, wherein the partitioning element at least partially seals the first compartment from the second compartment and enables the second compartment to have a greater pressurization than the first compartment. The chassis may further include at least one fan, wherein the at least one fan may be positioned in the first compartment. The chassis may further include a data processing unit, wherein the data processing unit may be positioned in the second compartment.

In another aspect, there is provided a method 800. The method 800 may include providing a chassis for a laptop arrangement, the chassis defining a space. The method 800 may include dividing the space into a first compartment and a second compartment. The method 800 may include at least partially sealing the second compartment from the first compartment with a partitioning element. The method 800 may include generating an airflow from the first compartment to the second compartment, whereby the first compartment may include an air inlet and the second compartment may include an air outlet, whereby the airflow pressurizes the second compartment. The method 800 may include removing heat generated by electronic components positioned in the second compartment.

In some aspects, the method 800 may further include positioning at least one fan in the first compartment to generate the airflow into the second compartment.

In some aspects, the laptop arrangement may further include an air seal gasket and the method 800 may include preventing the airflow moving from the second compartment back to the first compartment by using the air seal gasket.

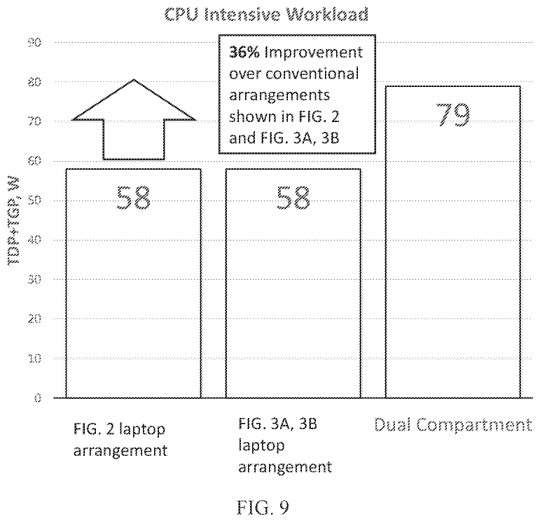

FIG. 8 shows a simplified flow diagram for an exemplary method 800 according to an aspect of the present method 800.

The operation 801 may be directed to providing a chassis for a laptop arrangement, the chassis defining a space.

The operation 802 may be directed to dividing the space into a first compartment and a second compartment.

The operation 803 may be directed to at least partially sealing the second compartment from the first compartment with a partitioning element.

The operation 804 may be directed to generating an airflow from the first compartment to the second compartment, whereby the first compartment includes an air inlet and the second compartment includes an air outlet, whereby the airflow pressurizes the second compartment.

The operation 805 may be directed to removing heat generated by electronic components positioned in the second compartment.

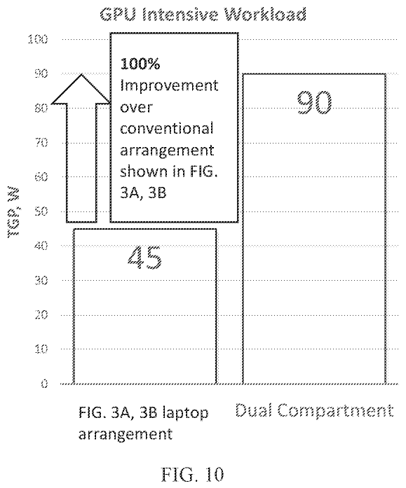

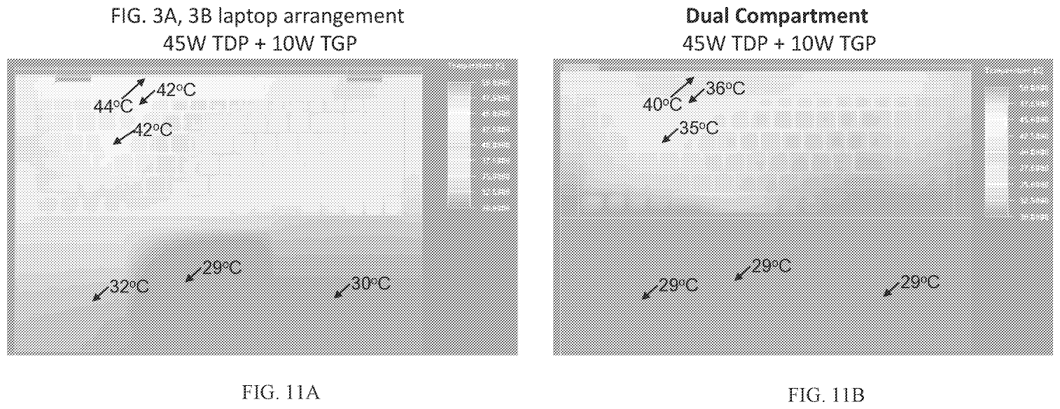

The effectiveness of the laptop arrangements 400, 500, 600, 700 and of the laptop including such laptop arrangements may be demonstrated in the following FIGS. 9-14. In particular, FIGS. 9 and 10 illustrate significantly improved thermal results using the “Dual compartment” design according to the aspects as presented herein. Measuring the CPU intensive workload ((FIG. 9), the thermal design power (TDP) and the total graphic power (TGP) could be improved by 36% over conventional laptop arrangements such as the conventional laptop arrangement shown in FIG. 2 or that of FIGS. 3A, 3B. The thermal capability of all configurations is limited by the keyboard skin temperature. The results are also illustrated in Table 1 below:

TABLE 1
CPU Intensive Workload Comparison

| | Thickness | | | |
|---|---|---|---|---|
| | of the | | | TDP + TGP |
| Configuration | chassis (mm) | TDP (W) | TGP(W) | (W) |
| conventional laptop | 10.3 | 58 | 0 | 58 |
| arrangement shown | | | | |
| in FIG. 2 | | | | |
| conventional laptop | 10.1 | 48 | 10 | 58 |
| arrangement shown | | | | |
| in FIGS. 3A, 3B | | | | |
| Dual Compartment | 10.1 | 69 | 10 | 79 |

Measuring the GPU intensive workload (FIG. 10), the thermal design power (TDP) and the total graphic power (TGP) could be improved by 100% over conventional laptop arrangements such as that described in FIGS. 3A, 3B. The results are also illustrated in Table 2 below:

TABLE 2
GPU Intensive Workload Comparison

| | Thickness | | | |
|---|---|---|---|---|
| | of the | | | TDP + TGP |
| Configuration | chassis (mm) | TDP (W) | TGP(W) | (W) |
| conventional laptop | 10.1 | 10 | 45 | 55 |
| arrangement shown | | | | |
| in FIGS. 3A, 3B | | | | |
| Dual Compartment | 10.1 | 10 | 90 | 100 |

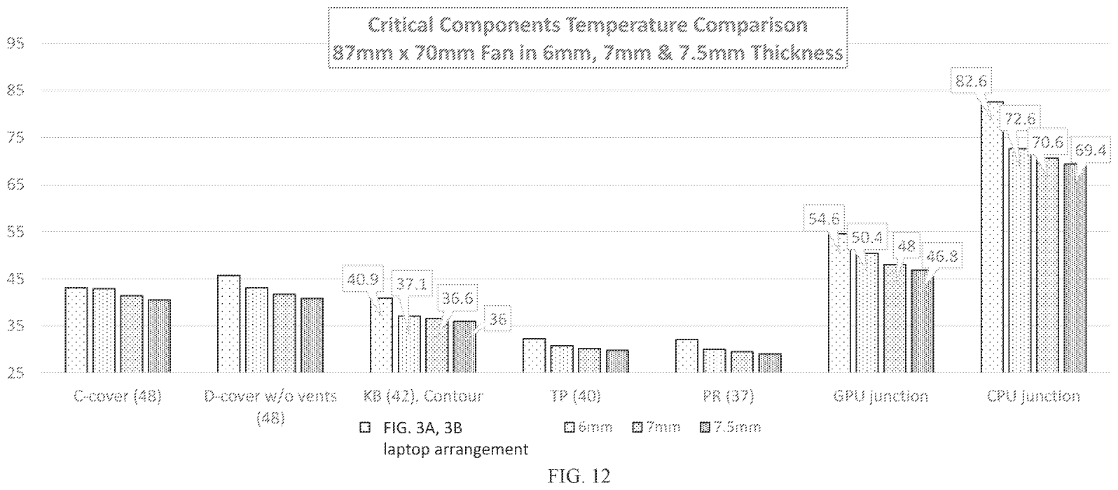

FIG. 11B illustrates a significantly lower keyboard skin temperature on critical components with the “Dual Compartment” laptop arrangement (especially the keyboard), as compared with a conventional laptop arrangement such as described in FIGS. 3A, 3B, and for which data are shown in FIG. 11A.

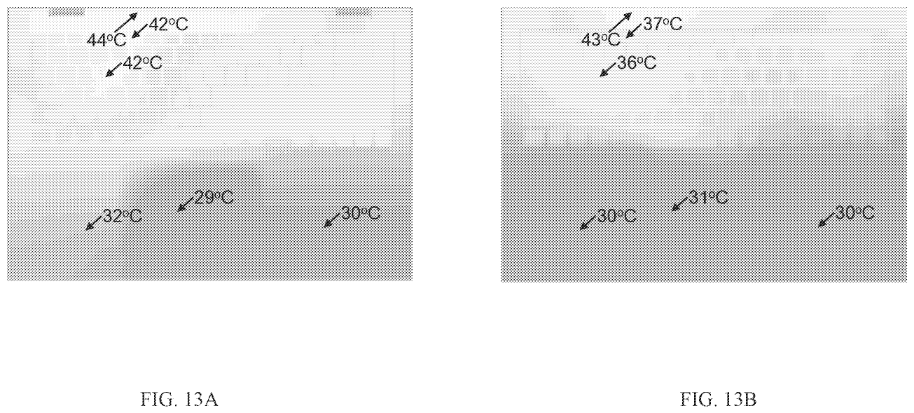

FIGS. 12-14 provide empirical support for the effectiveness of the “Dual Compartment”. In particular, thermal simulations were carried out on a laptop/clamshell chassis with 10.1 mm base stack. Numerous fan thicknesses (5 mm to 7.5 mm) were validated. Table 3 below shows the relationship between the fan thickness to the “fan P-Q performance” (i.e., the relationship between a static pressure (P) and an airflow rate (Q) of a fan, based on the AMCA 210 Standard). For ease of comparison, system power dissipation (45 W TDP+10 W TGP) is the same as that of conventional laptop arrangements described in FIGS. 3A, 3B.

TABLE 3
Fan Thickness vs. Fan P-Q

| Thickness | Pₘₐₓ | Qₘₐₓ |
|---|---|---|
| 5.0 | 0.5717 | 4.63 |
| 5.5 | 0.6248 | 5.70 |
| 6.0 | 0.6780 | 6.77 |
| 7.0 | 0.7843 | 8.91 |
| 7.5 | 0.8374 | 9.98 |

The “Dual compartment” thermal design allows for a fan having a thickness of, e.g., 7.5 mm as compared to conventional laptop arrangements described in FIGS. 3A, 3B, which may have a fan thickness of only 5 mm. This increased thickness is the result of the laptop arrangements 400, 500, 600, 700 described above, for a fixed thickness of the chassis (e.g., 10.1 mm). It was observed that the temperatures of all components decrease as the fan thickness increases, as illustrated in FIG. 12. On the keyboard, a reduction in temperature of up to 6° C. compared with conventional laptop arrangements described in FIGS. 3A, 3B was obtained. A significant reduction in temperature was also observed for the CPU junction, e.g., up to 13.2° C.

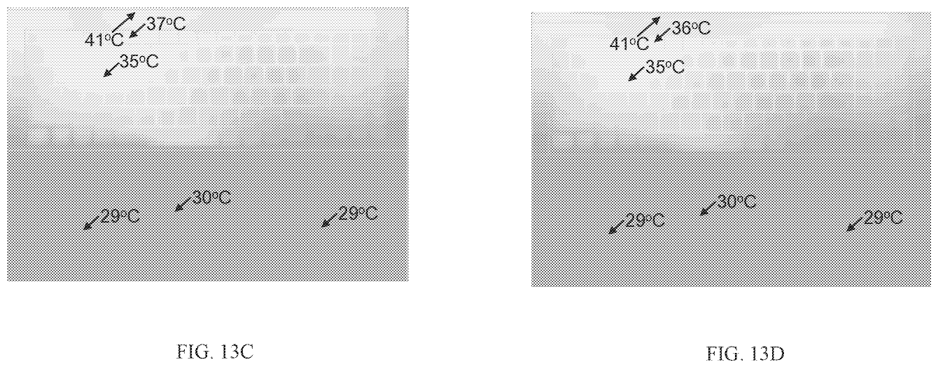

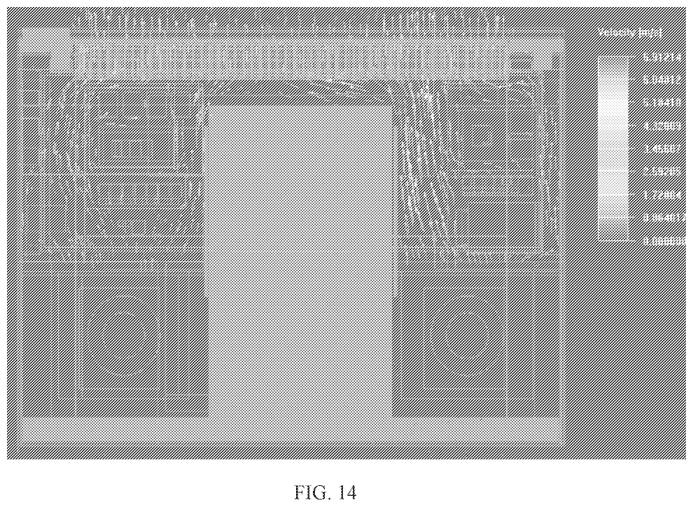

Referring now to FIGS. 13A-13D, compared with conventional laptop arrangements described in FIGS. 3A, 3B, the temperature contours measured on the surface of the chassis, e.g., the surface on which the keyboard and the touch pad are positioned, depict distinctive differences, especially on the keyboard region. In more detail, FIG. 13A refers to the conventional laptop arrangement described in FIGS. 3A, 3B, having a fan with a thickness of 5 mm. FIG. 13B refers to the “Dual Compartment” laptop arrangement, with a fan thickness of 6 mm, while FIGS. 13C and 13D refer to the “Dual Compartment” laptop arrangements, with fan thicknesses of 7 mm (FIG. 13C) and 7.5 mm (FIG. 13D). Due to a higher air velocity between the keyboard and the printed circuit board (PCB), better convective heat transfer (refer to FIG. 14 for details) reduces heat accumulation on keyboard, which leads to a lower temperature.

In a first example, there is provided a laptop arrangement including: a chassis defining a space that is divided into a first compartment and a second compartment, the first compartment including an air inlet and the second compartment including an air outlet; and a partitioning element positioned between the first and second compartments, whereby the partitioning element at least partially seals the first compartment from the second compartment and enables the second compartment to have a greater pressurization than the first compartment.

In a second example, the laptop arrangement of example 1 may include at least one fan, whereby the at least one fan may be positioned in the first compartment.

In a third example, the laptop arrangement of example 1 or example 2 may include a computing component, whereby the computing component may be positioned in the second compartment

In a fourth example, the computing component of example 3 may be selected from the group consisting of a motherboard, a central processing unit, a graphic processing unit, or a combination thereof.

In a fifth example, the laptop arrangement of any of the preceding examples may include a keyboard, whereby the keyboard may be positioned in the second compartment.

In a sixth example, whereby the at least one fan may include two fans, the laptop arrangement of example 2 may further include a touch pad, whereby the touch pad may be positioned in the first compartment and may be interposed between two fans.

In a seventh example, the laptop arrangement of example 6 may further include two regions configured as palm rest regions, whereby the two fans may be positioned below the two regions configured as palm rest regions.

In an eighth example, the laptop arrangement of any of the preceding examples may further include a thickness of the chassis, which may be less than about 13 mm.

In a ninth example, approximately 50% of the thickness of the chassis of example 8 may accommodate the at least one fan.

In a tenth example, approximately 70% of the thickness of the chassis of example 8 may accommodate the at least one fan.

In an eleventh example, the partitioning element of any of the preceding examples may be an air seal gasket.

In a twelfth example, the laptop arrangement of any of the preceding examples may further include a heat exchanger which may be positioned in the second compartment proximal to the air outlet.

In a thirteenth example, there is provided a laptop including: a chassis, whereby the chassis may define a space that is divided into a first compartment and a second compartment; the first compartment including an air inlet and the second compartment including an air outlet; whereby a partitioning element may be positioned between the first and second compartments, whereby the partitioning element may at least partially seal the first compartment from the second compartment and may enable the second compartment to have a greater pressurization than the first compartment. The laptop may further include a plurality of laptop components including: a computing component, two fans, a keyboard, a battery pack and a touch pad, whereby the keyboard and the computing component may be positioned in the second compartment, and the two fans and the touch pad may be positioned in the first compartment; whereby the computing component and the two fans may be positioned adjacent to each other within the chassis, whereby the keyboard may be positioned horizontally offset from the two fans, whereby the battery pack may be positioned vertically offset from the keyboard, and whereby the touch pad may be interposed between the two fans.

In a fourteenth example, the first compartment of example 13 may further include two regions configured as palm rest regions, whereby the two fans may be positioned below the two regions configured as palm rest regions.

In a fifteenth example, the computing component of example 13 or example 14 may be selected from the group consisting of a motherboard, a central processing unit, a graphic processing unit, or a combination thereof.

In a sixteenth example, the laptop of any of the preceding examples 13 to 15 may further include a thickness of the chassis to be less than about 13 mm.

In a seventeenth example, approximately 50% of the thickness of the chassis of example 16 may accommodate the at least one fan.

In an eighteenth example, there is provided a chassis for a laptop computer including: a first compartment and a second compartment, the first compartment including an air inlet and the second compartment including an air outlet; and a partitioning element positioned between the first and second compartments, wherein the partitioning element at least partially seals the first compartment from the second compartment and enables the second compartment to have a greater pressurization than the first compartment.

In a nineteenth example, the chassis of example 18 may further include at least one fan, wherein the at least one fan may be positioned in the first compartment.

In a twentieth example, the chassis of example 18 or example 19 may further include a data processing unit, wherein the data processing unit may be positioned in the second compartment.

The properties of the laptop arrangement and the choice of laptop components presented above are intended to be exemplary for the aspects of the disclosure. It will be apparent to those ordinary skilled practitioners that the foregoing process operations may be modified without departing from the spirit of the present disclosure.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

By “about” or “approximately” in relation to a given numerical value, such as for thickness and height, it is meant to include numerical values within 10% of the specified value.

While the present disclosure has been particularly shown and described with reference to specific aspects, it should be understood by those skilled in the art that various changes in form and detail may be made therein without departing from the spirit and scope of the present disclosure as defined by the appended claims. The scope of the present disclosure is thus indicated by the appended claims and all changes which come within the meaning and range of equivalency of the claims are therefore intended to be embraced.

1. A laptop arrangement comprising:
a chassis defining a space that is divided into a first compartment and a second compartment, the first compartment comprising an air inlet and the second compartment comprising an air outlet; and
a partitioning element positioned between the first and second compartments, wherein the partitioning element at least partially seals the first compartment from the second compartment and enables the second compartment to have a greater pressurization than the first compartment.

2. The laptop arrangement of claim 1, further comprising at least one fan, wherein the at least one fan is positioned in the first compartment.

3. The laptop arrangement of claim 1, further comprising a computing component, wherein the computing component is positioned in the second compartment.

4. The laptop arrangement of claim 3, wherein the computing component is selected from the group consisting of a motherboard, a central processing unit, a graphic processing unit, or a combination thereof.

5. The laptop arrangement of claim 1, further comprising a keyboard, wherein the keyboard is positioned in the second compartment.

6. The laptop arrangement of claim 2, wherein the at least one fan comprises two fans, and further comprising a touch pad, wherein the touch pad is positioned in the first compartment and is interposed between two fans.

7. The laptop arrangement of claim 6, further comprising two regions configured as palm rest regions, wherein the two fans are positioned below the two regions configured as palm rest regions.

8. The laptop arrangement of claim 1, wherein a thickness of the chassis is less than about 13 mm.

9. The laptop arrangement of claim 8, wherein approximately 50% of the thickness of the chassis accommodates the at least one fan.

10. The chassis of claim 8, wherein approximately 70% of the thickness of the chassis accommodates the at least one fan.

11. The laptop arrangement of claim 1, wherein the partitioning element is an air seal gasket.

12. The laptop arrangement of claim 1, further comprises a heat exchanger positioned in the second compartment proximal to the air outlet.

13. A laptop comprising:
a chassis, wherein the chassis defines a space that is divided into a first compartment and a second compartment; the first compartment comprising an air inlet and the second compartment comprising an air outlet; wherein a partitioning element is positioned between the first and second compartments, wherein the partitioning element at least partially seals the first compartment from the second compartment and enables the second compartment to have a greater pressurization than the first compartment;
a plurality of laptop components comprising:
a computing component, two fans, a keyboard, a battery pack and a touch pad, wherein the keyboard and the computing component are positioned in the second compartment, and the two fans and the touch pad are positioned in the first compartment;
wherein the computing component and the two fans are positioned adjacent to each other within the chassis,
wherein the keyboard is positioned horizontally offset from the two fans,
wherein the battery pack is positioned vertically offset from the keyboard, and
wherein the touch pad is interposed between the two fans.

14. The laptop of claim 13, wherein the first compartment further comprises two regions configured as palm rest regions, wherein the two fans are positioned below the two regions configured as palm rest regions.

15. The laptop of claim 13, wherein the computing component is selected from the group consisting of a motherboard, a central processing unit, a graphic processing unit, or a combination thereof.

16. The laptop of claim 13, wherein a thickness of the chassis is less than about 13 mm.

17. The laptop of claim 16, wherein approximately 50% of the thickness of the chassis accommodates the at least one fan.

18. A chassis for a laptop computer comprising:
a first compartment and a second compartment, the first compartment comprising an air inlet and the second compartment comprising an air outlet; and
a partitioning element positioned between the first and second compartments, wherein the partitioning element at least partially seals the first compartment from the second compartment and enables the second compartment to have a greater pressurization than the first compartment.

19. The chassis of claim 18, further comprising at least one fan, wherein the at least one fan is positioned in the first compartment.

20. The chassis of claim 18, further comprising a data processing unit, wherein the data processing unit is positioned in the second compartment.
